(19) United States
(12) Patent Application Publication
(10) Pub. No.: US 2021/0126192 A1
(43) Pub. Date: Apr. 29, 2021

(54) Silicon Compatible Tin-based Cationic Filamentary Device

(71) Applicant: The University of Chicago, Chicago, IL (US)

(72) Inventors: Sushant Sonde, Westmont, IL (US); Supratik Guha, Chicago, IL (US)

(21) Appl. No.: 17/042,691

(22) PCT Filed: Apr. 12, 2019
(86) PCT No.: PCT/US2019/027145

§ 371 Date: Sep. 28, 2020

Related U.S. Application Data
(60) Provisional application No. 62/656,697, filed on Apr. 12, 2018.

(51) Int. Cl. H01L 45/00; G11C 13/00; H01L 27/24

(52) U.S. Cl. CPC H01L 45/1266; G11C 13/0011; H01L 45/085; H01L 27/2463; H01L 45/147; H01L 45/1616; H01L 45/146

(57) ABSTRACT

The present disclosure describes devices, systems, and methods of manufacture that relate to cationic filamentary (CF) devices. An example CF device includes a first electrode, a second electrode, and an insulator. The first electrode includes an electrochemically inert material. The second electrode includes an electrochemically active material. The electrochemically active material includes Sn, An insulator disposed between the first electrode and the second electrode such that a positive voltage applied to the second electrode with respect to the first electrode causes formation of a conductive filament in the insulator extending from the second electrode toward the first electrode.

### CROSS-REFERENCE TO RELATED APPLICATIONS

The present patent application claims priority to U.S. Provisional Application No. 62/656,697 filed Apr. 12, 2018, the contents of which are hereby incorporated by reference.

### GOVERNMENT LICENSE RIGHTS

This invention was made with government support under DE-AC02-06CH11357 awarded by the Department of Energy and government support under 1640081 awarded by the National Science Foundation. The government has certain rights in the invention.

### BACKGROUND

Large banks of cheap, fast, non-volatile, energy efficient, scalable solid-state memories are an increasingly common component for today's data-intensive computing. Conductive-bridge random access memory (CBRAM)—which involves voltage-driven formation and dissolution of electrically-conductive Cu or Ag filaments in a Cu (or Ag) anode/dielectric (HfO₂ or Al₂O₃)/inert cathode device—possesses the necessary attributes to fit the requirements. Cu and Ag are, however, fast diffusers and known contaminants in silicon microelectronics.

### SUMMARY

The present disclosure generally relates to silicon compatible Sn-based cationic filamentary device.

In a first aspect, a cationic filamentary (CF) device is provided. The CF device includes a first electrode and a second electrode. The first electrode includes an electrochemically inert material. The second electrode includes an electrochemically active material. The electrochemically active material includes Sn. The CF device also includes an insulator disposed between the first electrode and the second electrode such that a positive voltage applied to the second electrode with respect to the first electrode causes formation of a conductive filament in the insulator extending from the second electrode toward the first electrode.

In a second aspect, a system is provided. The system includes a plurality of cationic filamentary devices disposed in a crossbar arrangement. Each cationic filamentary device of the plurality of cationic filamentary devices includes a first electrode, a second electrode, and an insulator disposed between the first electrode and the second electrode. The first electrode includes an electrochemically inert material. The second electrode includes an electrochemically active material. The electrochemically active material includes Sn.

In a third aspect, a method of manufacture of a cationic filamentary device is provided. The method includes depositing a first electrode on a substrate. The first electrode includes an electrochemically inert material. The method includes depositing an insulator on the first electrode. The method additionally includes depositing a second electrode on the insulator. The second electrode includes an electrochemically active material. The electrochemically active material includes Sn.

Other aspects, embodiments, and implementations will become apparent to those of ordinary skill in the art by reading the following detailed description, with reference where appropriate to the accompanying drawings.

### BRIEF DESCRIPTION OF THE FIGURES

FIG. 1 illustrates a device, according to an example embodiment.

FIG. 2 illustrates diffusion coefficients for Sn, Ag, and Cu, according to example embodiments.

FIG. 3 illustrates cohesive energy for Au, Cu, Pt, and Hf, according to an example embodiment.

FIG. 4 illustrates heat of formation of metal oxide for Ag, Cu, Hf, and Pt, according to an example embodiment.

FIG. 5 illustrates ionic radius for Pt, Hf, Cu, Ag, and O, according to an example embodiment.

FIG. 6 is a schematic illustration of crossbar devices, according to an example embodiment.

FIG. 7 is a cross-sectional schematic illustration of a device, according to an example embodiment.

FIG. 8 illustrates fabricated crossbar structures, according to an example embodiment.

FIG. 9 illustrates fabricated devices, according to an example embodiment.

FIG. 10 illustrates a cross-sectional transmission electron micrograph and corresponding energy dispersive x-ray spectroscopy line-scan, according to an example embodiment.

FIG. 11 illustrates unipolar, bidirectional threshold switching and corresponding statistical distribution of measured threshold voltages, according to an example embodiment.

FIG. 12A illustrates memory switching, according to an example embodiment.

FIG. 12B illustrates a statistical distribution of measured threshold voltages, according to an example embodiment.

FIG. 12C illustrates a statistical distribution for current measured at high resistance state (I_{HRS}), according to an example embodiment.

FIG. 13 illustrates a memory retention study performed at various temperatures, according to an example embodiment.

FIG. 14 illustrates a method, according to an example embodiment.

FIG. 15 illustrates a method, according to an example embodiment.

### DETAILED DESCRIPTION

Example methods, devices, and systems are described herein. It should be understood that the words “example” and “exemplary” are used herein to mean “serving as an example, instance, or illustration.” Any embodiment or feature described herein as being an “example” or “exemplary” is not necessarily to be construed as preferred or advantageous over other embodiments or features. Other embodiments can be utilized, and other changes can be made, without departing from the scope of the subject matter presented herein.

Thus, the example embodiments described herein are not meant to be limiting. Aspects of the present disclosure, as generally described herein, and illustrated in the figures, can be arranged, substituted, combined, separated, and designed in a wide variety of different configurations, all of which are contemplated herein.

Further, unless context suggests otherwise, the features illustrated in each of the figures may be used in combination with one another. Thus, the figures should be generally viewed as component aspects of one or more overall embodiments, with the understanding that not all illustrated features are necessary for each embodiment.

### I. Overview

In the present disclosure, devices, systems, and methods are described that could provide a silicon CMOS-compatible replacement for Cu and Ag anodes in cationic filamentary (CF) devices.

Specifically, by employing a criterion for electrode metal selection applicable to cationic filamentary devices and using first principles calculations for estimating diffusion barriers in HfO₂, tin (Sn) has been identified as a potential candidate for incorporation into a cationic filamentary device. Such Sn-based cationic filamentary devices have been fabricated and they demonstrate very fast, steep-slope memory switching as well as threshold switching, comparable to Cu or Ag-based devices. Furthermore, time evolution of the cationic filament formation along with the switching mechanism has been quantified based on time domain measurements (I vs. t) carried out under constant voltage stress. The time to threshold was shown to be a function of both the voltage stress (Vₛₜᵣₑₛₛ) as well as the initial leakage current (I₀) through the device.

Resistive switching devices that utilize the formation of an electric field-driven conductive metallic filament in a dielectric layer are being extensively studied for non-volatile memory, as non-volatile switches in reconfigurable circuits and as synaptic elements in biologically inspired computing applications. A conductive-bridge random access memory (CBRAM) device an example of such a resistive switching device.

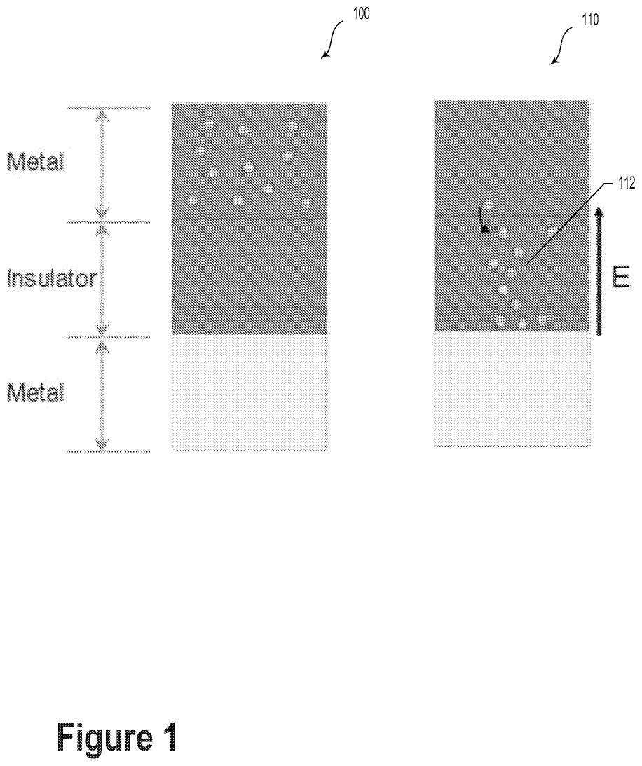

Conventionally, these device structures could include a dielectric oxide thin film such as HfO₂ or Al₂O₃ (as switching matrix) and an inert (e.g., W or Pt) cathode and an electrochemically active (e.g., Cu or Ag) anode on either side of the dielectric oxide thin film. Under voltage bias, electrochemical migration of Cu or Ag ions from the anode leads to formation of a propagating conducting filament between the cathode and anode, leading to a non-volatile change in the resistance of the device. These cationic filamentary devices offer large (up to 10 orders of magnitude) high/low resistance ratio and excellent (low) cycle-to-cycle (C2C) variability. FIG. 1 illustrates an example cationic filamentary device that could provide a first electrochemical state 100 and a second electrochemical state 110 after electrochemical migration of cations to form a conductive filament 112, according to an example embodiment. The conductive filament 112 could include, for example, an electrically-conductive pathway for current to pass through the CF device (e.g., between a first electrode and a second electrode of the device). Such a pathway could be formed with a certain concentration of metallic ionic species and/or a metallic structure of the CF device.

Conventional CF type devices studied to date have been based on the diffusion of Cu and Ag ions for filament formation. However, these metals are known fast diffusers in silicon and present the risk of severe contamination when integrated into silicon circuitry. Overcoming this contamination issue requires introduction of diffusion barriers (as is done in Cu interconnect technology), in turn limiting design options and increasing complexity. For instance, in the cases where the memory element is connected in series with a silicon transistor or a selector device in order to suppress leakage currents, a fast diffuser such as Cu or Ag risks contaminating the transistor or selector.

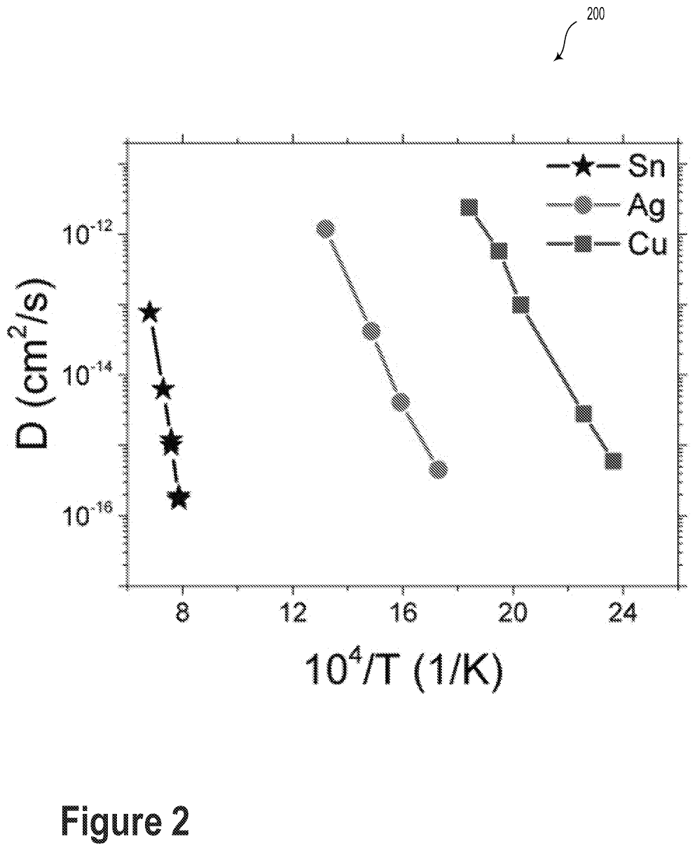

In the present disclosure, a criterion—based on established and computed materials parameters—is provided for electrode metal selection applicable to cationic filamentary devices. Using this criterion, it is observed that alternative metals—such as Sn—can be used instead of Cu or Ag as the cationic filament forming element in CF structures. Furthermore, successful fabrication and reversible resistance switching has been demonstrated using Sn as the anode in CF devices, consistent with predictions. Unlike the aliovalent Cu and Ag, which create electronically active defect centers in Si, Sn offers the major advantage in being CMOS-friendly: it is isovalent with Si and can be incorporated in significant amounts on Si substitutional lattice sites without creating electrically active defects. It is also a slower diffuser in Si than Cu and Ag, for comparable temperature ranges reducing contamination risk. FIG. 2 illustrates diffusion coefficients 200 for Sn, Ag, and Cu, according to example embodiments.

Resistive switching phenomena in cationic filamentary devices have been demonstrated in many oxides, chalcogenides (sulfides, iodides, selenides, tellurides, ternary chalcogenides) and others (methylsilsesquioxane (MSQ), doped organic semiconductors, nitrides, amorphous Si, Carbon, vacuum gaps). However, all the above-listed demonstrations have involved changing the insulating matrix while restricting the anode (filament forming) metal to Cu or Ag. Here, a criterion—consisting of three material parameters—is provided that not only justifies the use of Cu or Ag as most common anode for cationic filamentary devices, but also suggests other viable candidate metals for such applications. Investigating other anode metals would allow more anode/insulator combinations, providing better performing devices and devices with specific characteristic features and functionality.

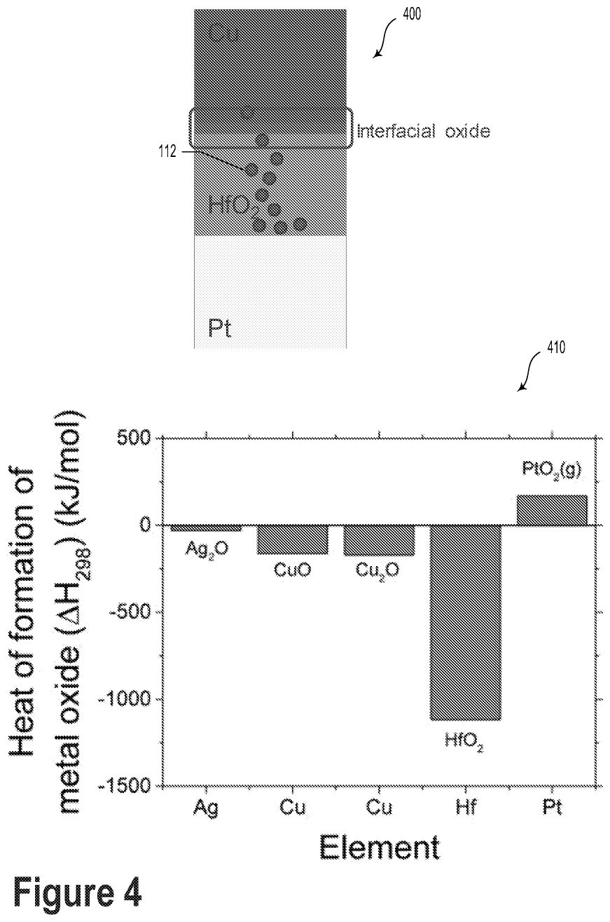

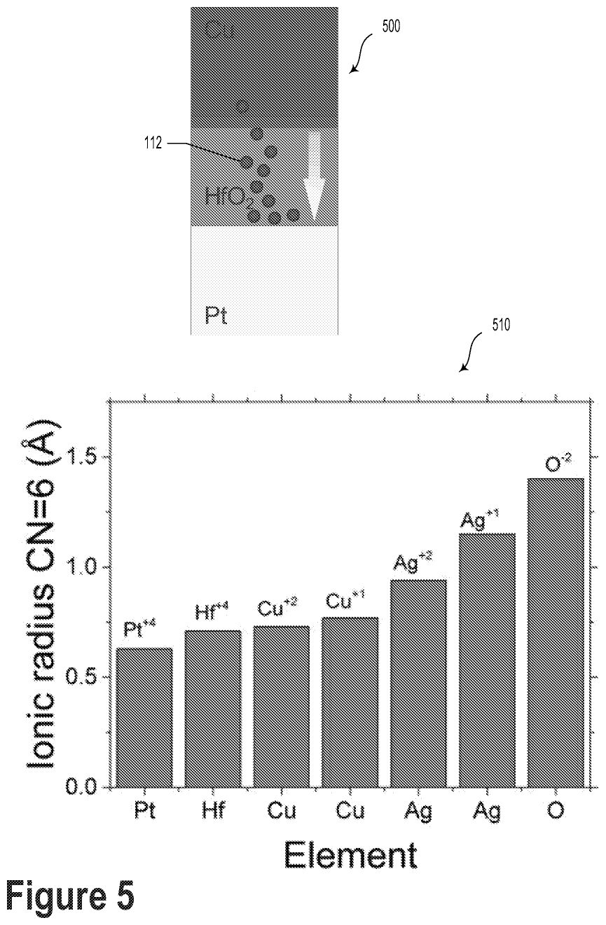

For low energy switching of non-volatile memory that utilizes filament formation, three components are considered, each relating to the energetic cost of creating a filament across the Metal-Insulator-Metal (MIM) stack. If the anode is in direct contact with the dielectric oxide, there is the energy cost of moving the metal atoms from the anode into the dielectric oxide. An indicator of this energy cost is the cohesive energy for the metal (Ec). If there is an interfacial anodic oxide layer between the anode metal and the dielectric (e.g., interfacial oxide 400 as illustrated in FIG. 4), then one should consider the energy cost of extracting the metal atom from the anodic oxide: this is related to the heat of formation of anode metal oxide (ΔH). The third component is work done to transport the anode metal atom across the dielectric oxide to the cathode by drift driven diffusion (e.g., diffusion process 500 as illustrated in FIG. 5). Assuming all other parameters for drift to be the same, in general, a smaller ionic radius will lead to a lower activation barrier for diffusion, which may be desirable. Thus, in general, for low energy cationic filament formation, smaller E_{c} of the anode metal, lower ΔH of anode metal oxide and smaller ionic radius may be desired. FIG. 5 illustrates ionic radius 510 for Pt, Hf, Cu, Ag, and O, according to an example embodiment.

In conventional CF devices, Ag and Cu have been very common choice of anode metal for cationic filamentary devices due to their small E_{c} and low ΔH. FIG. 4 illustrates heat of formation 410 of metal oxide for Ag, Cu, Hf, and Pt, according to an example embodiment.

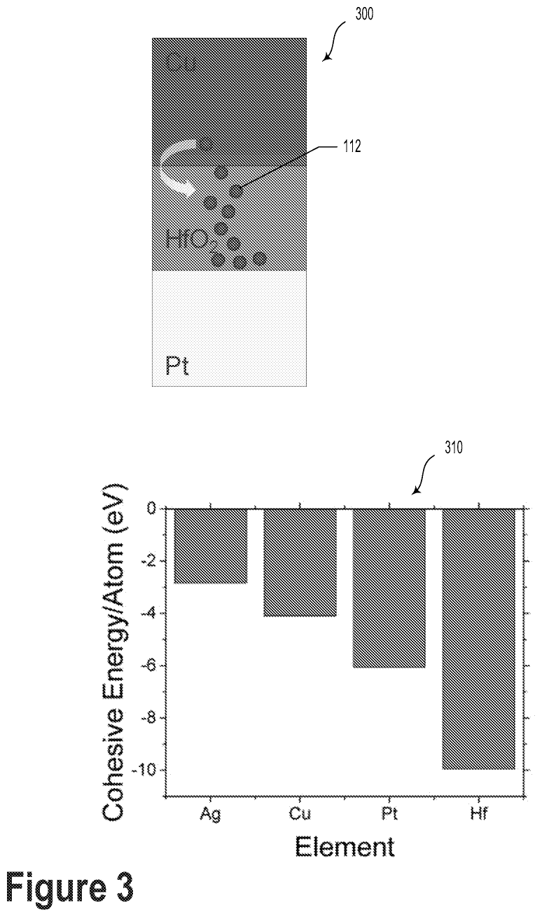

This criterion can also be applied to other metals to determine their suitability for use as anode for formation of low energy cationic filament (e.g., filament formation 300 as illustrated in FIG. 3). Based on this criterion, Sn is identified as a viable candidate metal as follows. Density functional theory (DFT) is utilized to derive cohesive energies and heat of formation of oxide for Cu, Ag, Sn, and other materials. FIG. 3 illustrates cohesive energies 310 for Au. Cu, Pt, and Hf, according to an example embodiment.

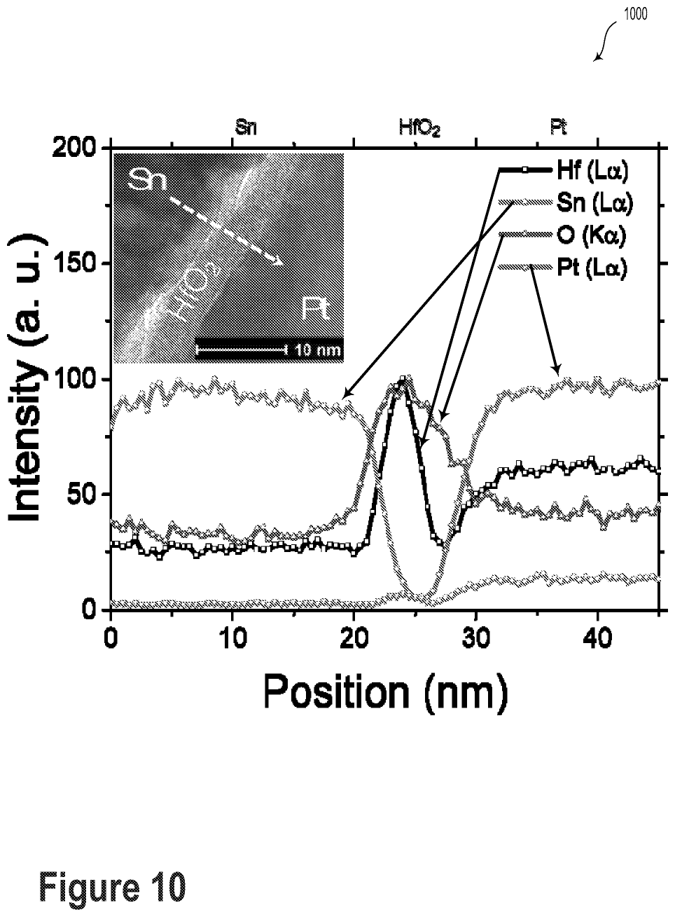

Cohesive energy of Sn is slightly higher than Ag, but comparable to Cu. The heat of formation of SnO₂ is moderately higher than Cu₂O and Ag₂O. DFT-based first principles calculations were conducted in order to estimate the activation barrier for Sn diffusion within HfO₂. FIG. 10 illustrates a cross-sectional transmission electron micrograph and corresponding energy dispersive x-ray spectroscopy line-scan, according to an example embodiment.

Density functional theory (DFT) calculations were carried out using the Vienna Ab initio Simulation Package (VASP). The projector augmented wave method was applied to describe the interactions between valence electrons and frozen cores. An energy cutoff of 600 eV was used. All calculations used spin-polarized DFT. The Perdew-Burke-Emzerhof (PBE) form of the generalized gradient approximation (GGA) was used to describe the exchange and correlation interactions. The Gaussian smearing method with a width of 0.1 eV around the Fermi level was applied to facilitate convergence. The electronic energies were converged to 10⁻⁶ eV. Ionic relaxations were performed until the residual forces on ions were less than 0.02 eV A⁻¹. A 1×1×1 Γ-centered k-point mesh was chosen to reduce the computational cost. The nudged elastic band (NEB) method with climbing images was used for diffusion energy barrier calculations. The charge density difference was computed for the transition state along the diffusion pathway. The system was divided into two subsystems for the charge density difference (CDD) calculations, using the Cu/Ag/Sn as one subsystem and the HfO₂ as the second subsystem. Bader charges were also computed for the various ions in HfO₂.

The results of the calculations indicate that the activation barrier for Sn diffusion (˜0.54 eV) within HfO₂ is lower than that for Ag (0.72 eV) and Cu (1.16 eV). To understand this low barrier for Sn, further calculations describe the charge density difference and Bader charges for Sn at the transition state, namely the highest total energy state as it diffuses from one interstitial site to another. Compared to Cu and Ag, such calculations suggest a substantial amount of charge depletion for Sn at the transition state as it is repelled by its two nearest neighboring O atoms from both sides. This increased charge depletion leads to a much smaller ionic radii leading to faster Sn diffusion in HfO₂ compared to Ag and Cu. The predicted low diffusion barrier for Sn in HfO₂, coupled with the relatively low oxide heat of formation and cohesive energy suggest that Sn can potentially be a good candidate for filament-based non-volatile memories.

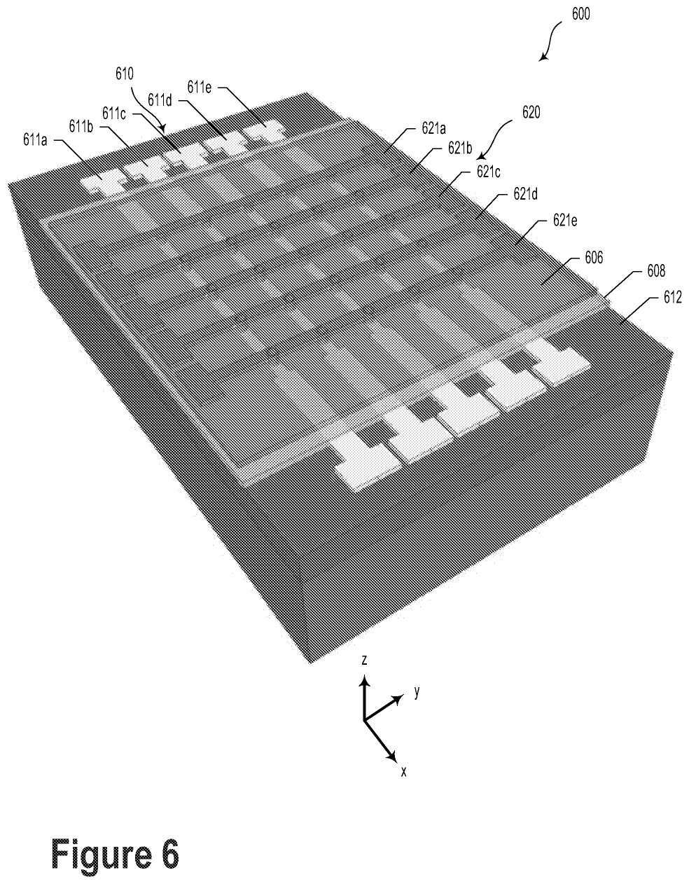

FIG. 6 is a schematic illustration of system 600, according to an example embodiment. System 600 includes vertical MIM devices in a crossbar geometry that were fabricated on SiO₂ (300 nm thick)/Si substrates. Sputter-deposited bottom electrodes, Cr/Pt (5 nm/50 nm), were patterned using (photolithography) electron-beam lithography and lift-off process. Plasma enhanced chemical vapor deposition (PECVD) was then used to deposit 100 nm thick SiO₂ field oxide on the Cr/Pt electrode array, followed by dry etch to open windows down to the Cr/Pt in the field oxide. Atomic layer deposition (ALD) was then used to conformally deposit HfO₂ (4 nm thick, 200° C., Tetrakis(ethylmethylamino) hafnium (TEMAHf) from PURATREM and H₂O precursor) in the windows, followed by the lithography, sputter deposition and lift-off of the Sn (50 nm) top electrode and a Au capping layer. This resulted in a Cr/Pt/HfO₂/Sn/Au device stack with HfO₂ acting as the switching medium and the SiO₂ field oxide providing accurate device area definition and isolation.

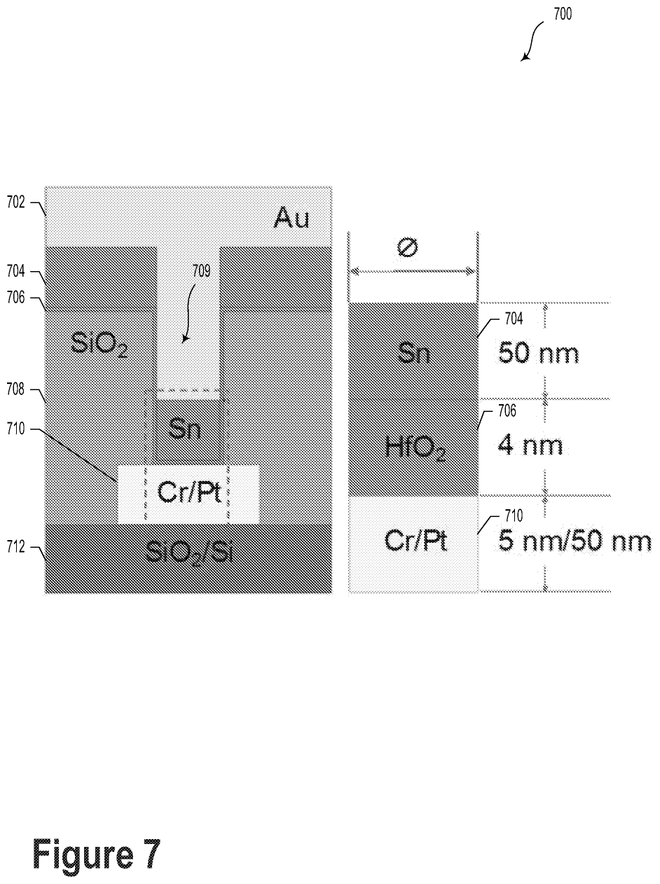

FIG. 7 is a cross-sectional schematic illustration of a device 700, according to an example embodiment. The device sizes varied from 100 μm diameter circles down to 100 nm diameter circles. The DC sweeps of the devices were measured using Keysight B1500A semiconductor parameter analyzer. Switching characteristics using pulsed measurements were measured using Keysight 33600A Series Trueform Waveform Generator and Keysight DS0204A Infiniium S-Series oscilloscope. The use of Sn as an anode (and hence active filament forming element) has not been demonstrated before even though the use of Sn is benign in Si technology.

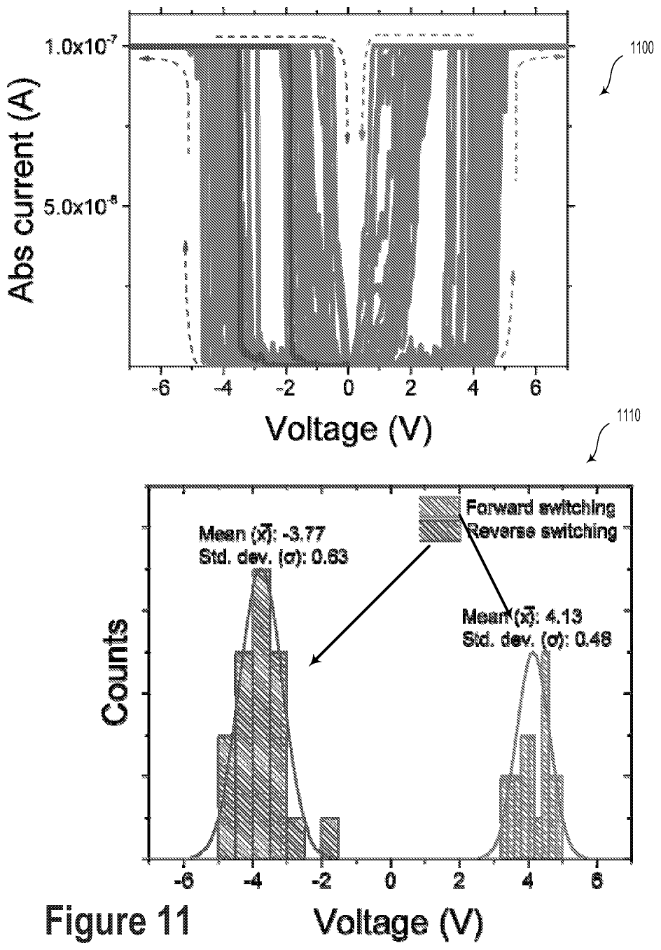

Current-voltage traces 1100 of FIG. 11 illustrate typical responses of the as-fabricated devices under electric bias, according to example embodiments. The as-fabricated devices had a high resistance (typically >10¹⁰Ω at 100 mV for all devices). This high resistance state is referred to as the OFF-state resistance. With positive bias applied to the Sn electrode (forward bias condition, Sn as the anode), the device current increased abruptly to the applied current compliance (100 nA) beyond a threshold voltage (Vₜₕ). However, the device returned to its high resistance state while sweeping the bias voltage back to zero. On the other hand, no change in the device resistance was observed when positive bias was applied to the Pt electrode (Pt as anode) when the device was operated for the very first time.

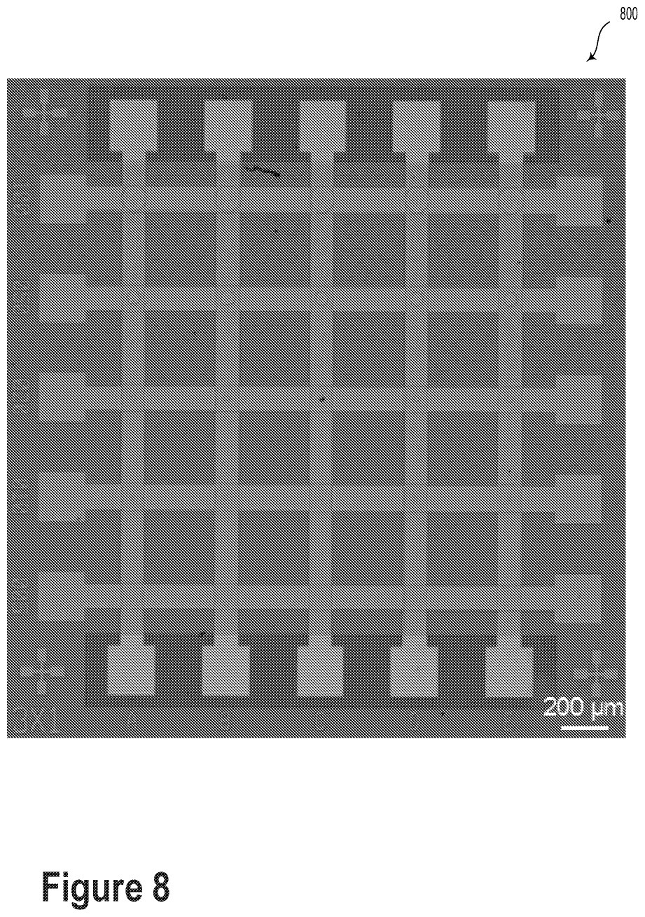

However, illustrated in FIG. 11, when a prior voltage sweep using Sn as the anode was implemented, bidirectional threshold switching was enabled and the device subsequently changed resistance beyond a threshold voltage even when the Pt electrode was used as the anode. This observation is consistent with an electrochemical ionic drift model which would require a small amount of anode metal (Sn) to initially migrate to the vicinity of the Pt electrode for bidirectional switching to occur. Such bidirectional volatile switching behavior is useful in selector-switch application for large arrays of crosspoint memory. FIG. 8 illustrates fabricated crossbar structures 800, according to an example embodiment.

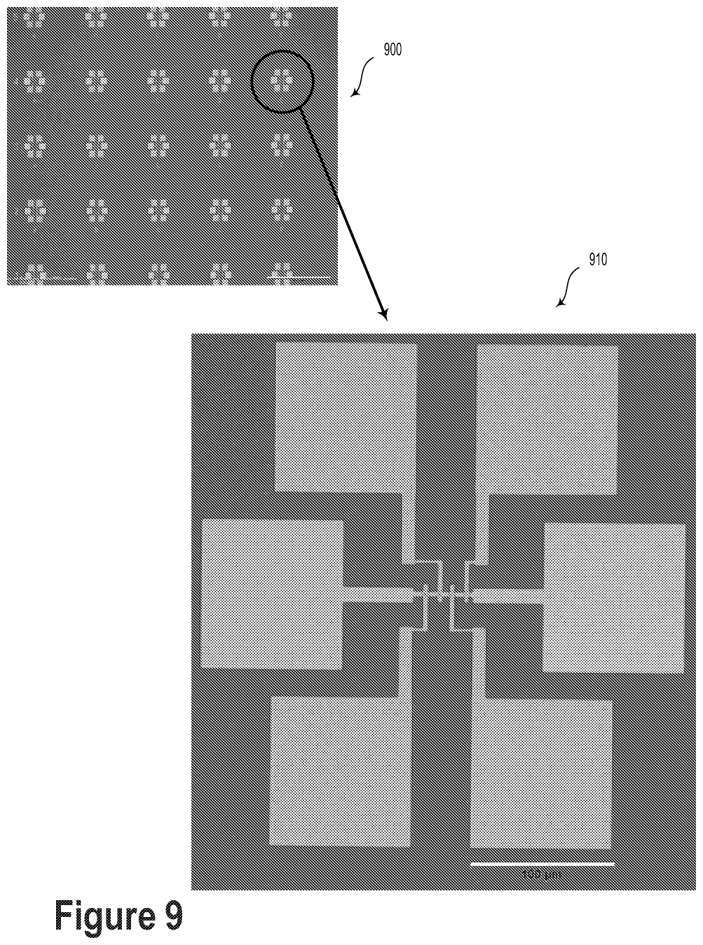

The threshold voltages observed in this study are ˜67% higher than devices based on similar thickness of HfO₂ using Cu and Ag anodes. Although, the threshold values measured for such devices are higher than that of Cu and Ag based devices, it is not necessarily a drawback. Rather, in the case of a large array of 1S1R (1 selector-1 resistor) cell, such a property can be desirable. Too low threshold voltages have a drawback in not providing a sufficient operating window for large arrays of 1S1R. For example, in the case where Vₜₕ is too low (Vₜₕ<½V_{cell}), the selector could be unable to prevent leakage current from flowing into unselected cells. ½V_{cell} is the voltage applied to unselected cells. On the other hand, higher Vₜₕ can control the leakage current without disturbing the unselected cells. Nevertheless, threshold voltages are subject to the material stack and can be engineered to occur at lower values, if required, for low power applications e.g. by means of doping the switching matrix. Large numbers (100 sweeps) of consecutive DC cycles of the measured threshold switching were applied and the corresponding statistical distribution 1110 of Vₜₕ is illustrated in FIG. 11. The mean (x̅) Vₜₕ found for these devices is 4.13 V (standard deviation, σ=0.48 V). FIG. 9 illustrates a fabricated device 910 from a plurality of devices 900, according to an example embodiment.

It is desirable for selector switches to withstand the chip operating temperature. Experimental measurements demonstrated the multiple stable threshold switching measured at 90° C. Furthermore, the turn-on slope of resistive switching devices is an important parameter. A steep turn-on slope is important considering their possible use in large, dense crossbar array as well as in novel devices aimed at ultra-scaled operating voltages. The typical turn-on slope observed in Sn-based devices is about 8.75 mV per decade, being similar to turn-on slopes for Cu and Ag based devices, and is appropriate for non-volatile memory applications. There is experimental evidence in CBRAM devices that the pulse width required to trigger a set or reset event depends exponentially on the amplitude of the applied pulse. Considering this, a 4 V amplitude and 50 ns width pulse was applied with an external pulse generator, and the switching speed was found to be about 17 ns. Cu and Ag-based selector devices have shown switching speeds in the same order of magnitude. Thus Sn-based resistive switching devices offer similar advantages as Cu and Ag-based devices, but with less risk of contamination in a silicon chip fabrication environment.

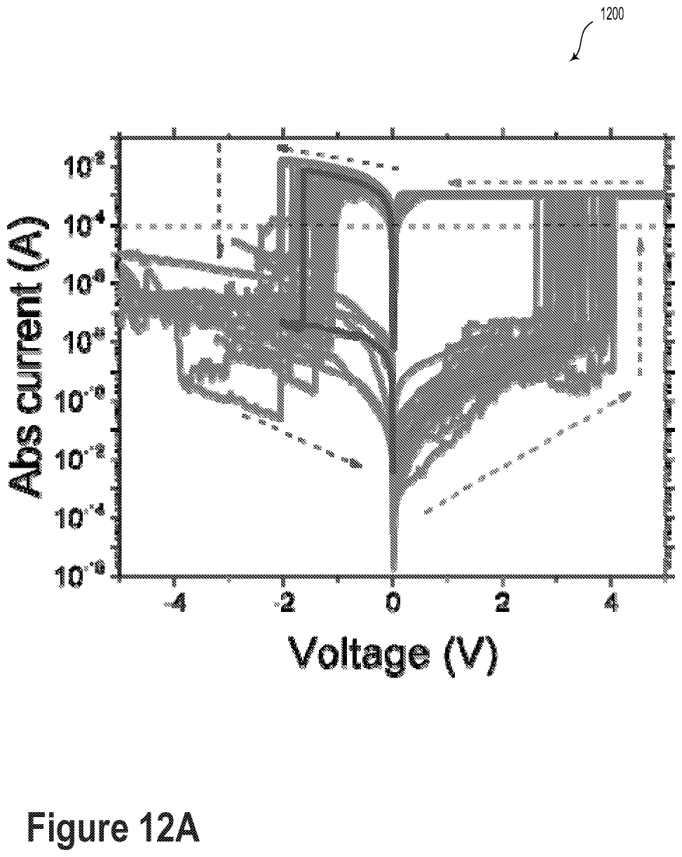

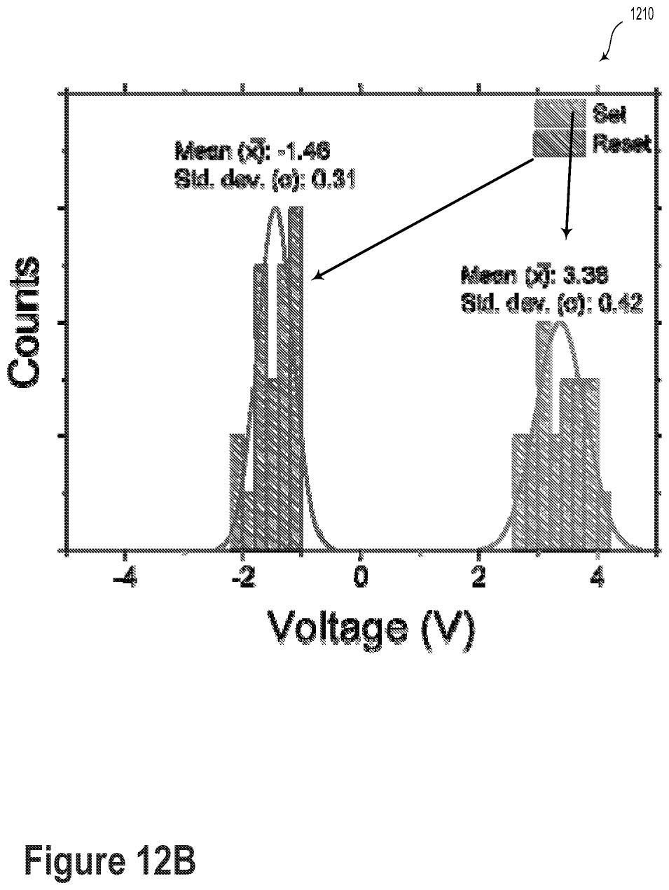

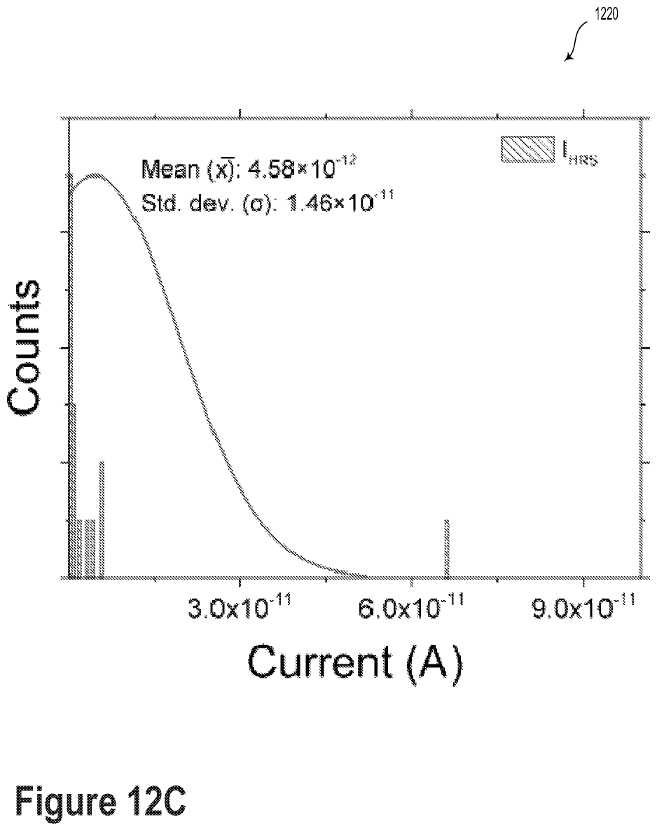

In response to the modulation of compliance current (I_{cc}), Sn-based devices exhibit coexistence of threshold and memory switching behavior. This is due to the inverse relationship between the read resistance (post the device turn ON) in the resistive switching device and the set compliance current commonly observed. Similar behavior has been reported in other resistive switching devices. This can be more simply understood in the case of cationic filamentary devices by considering that a larger compliance current would supply more metal ions to form a stronger conducting filament when the low resistance state occurs. This explanation is experimentally supported through observation of an increase in physical volume of the conducting filament with increased compliance current. FIGS. 12A, 12B, and 12C illustrate memory switching 1200, corresponding statistical distribution 1210 of measured threshold voltages, and statistical distribution 1220 for current measured at high resistance state (I_{HRS}), according to example embodiments.

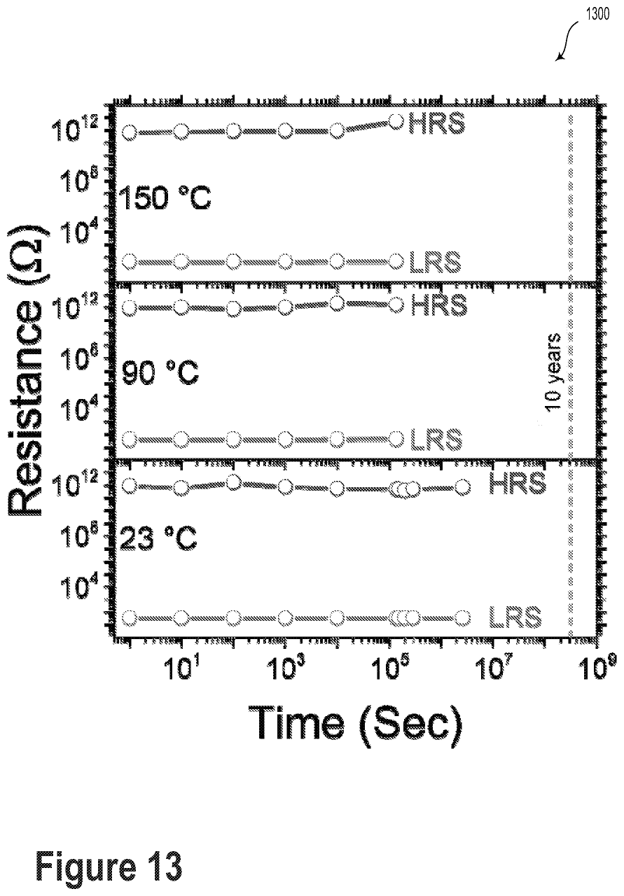

FIG. 11 illustrates unipolar, bidirectional threshold switching 1100 and corresponding statistical distribution 1110 of measured threshold voltages, according to an example embodiment. A large number (150 sweeps) of measured consecutive DC cycles is shown in FIG. 11 along with the statistical distribution for V_{Set} and V_{Reset}. The mean (x̅) V_{Set} and V_{Reset} found for these devices is 3.36 V (standard deviation, σ=0.42 V) and 1.46 V (standard deviation, σ=0.31 V). Also, the mean (x̅) current measured at high resistance state (IHRS) is 4.58×10⁻¹² A (standard deviation, σ=1.46×10⁻¹¹ A). A data retention time longer than ten years is expected for nonvolatile memory. Extensive time dependent measurements 1300 of stable retention data collected for Sn-based nonvolatile memory are presented in FIG. 13. The resistance of the high and low resistive states was determined by measuring the current at a small bias of 100 mV. The ratio of the high resistive to low resistive state (the “memory window”), as can be seen from FIG. 13 is >10¹⁰. This is similar to, or larger than the ON/OFF ratios (10⁷) for cationic filamentary devices that have been reported in Cu/HfO₂ and Ag/HfO₂ systems. Considering that the memory retention should withstand thermal stresses, measurements were performed at room temperature as well as elevated temperatures, 90° C. (chip operating temperature) and 150° C. Very stable retention (x ⁻HRS=7-10¹¹Ω, σHRS=3.69×10¹¹, x ⁻LRS=34.57Ω, σLRS=0.18 at 23° C., x ⁻HRS=1.28×10¹²Ω, σHRS=5.64×10¹¹, x ⁻LRS=40.90Ω, σLRS=1.24 at 90° C., x ⁻HRS=1.48×10¹²Ω, σHRS=1.68×10¹², x ⁻LRS=44.97Ω, σLRS=0.76 at 150° C.) that withstood thermal as well as small electrical stresses of read voltages (100 mV) was observed.

Sn₂O being more stable under thermal stresses (considering Sn₂O has more negative heat of oxide formation compared to Cu₂O, Ag₂O) than Cu₂O and Ag₂O, Sn-based devices are potentially advantageous in achieving stable resistive switching performance over a longer period of time than Cu or Ag electrodes. This is deduced from the fact that interfacial oxide between the anode and switching matrix plays an important role in filament formation, as described earlier. Retention of non-volatile states, lasting up to four weeks (for room temperature and 40 hours each for elevated temperatures) as tested, is already sufficient for certain neuromorphic applications involving short and medium term plasticity. Among the highest priority for CBRAM devices is the cycling endurance since this amongst the strongest concerns for the device reliability. FIG. 13 illustrates a memory retention study 1300 performed at various temperatures, according to an example embodiment. The manual endurance data (225 DC cycles) may not yet meet the standards set forth by other resistive switching devices. However. Sn-based CBRAM devices are in the initial phases of development and achieving endurance >10⁶ cycles by pulsed cycling endurance test will be of importance for practical applications and hence will be focus of future studies. In this disclosure, Sn has been successfully demonstrated as the filament forming species in oxide matrix. However, a Sn anode can also be potentially used in chalcogenide-based resistive switching devices. The Sn anode can either be used to instigate a phase change, Phase change memory (PCM), in GeTe or Ge₂Se₃ films or as migrating ion source for CBRAM memory. The switching mechanism is discussed next.

Experiments to determine the time dependent response of the measured current through the devices under constant voltage stress were conducted. The voltage stress was varied from 0.5 V to 2.5 V, the threshold at which the resistive state changes abruptly. The temporal response of the current followed three stages: (i) an initial decrease that varies as tⁿ (with n˜−0.72 to −0.08 as the voltage increases from 0.5 V to 2.25 V). (ii) a gradual increase in current, followed by (iii) a sharp increase indicative of an abrupt change in the resistive state. For low voltages, stages (ii) and (iii) do not appear. This incubation time leading to stage (iii) is inversely proportional to the voltage. The initial decrease (stage (i)) has been associated with dielectric relaxation processes and the creation of charge traps. The slight increase in current in stage (ii) may be related to stress-induced-leakage-current (SILC). Stage (iii) is indicative of the formation of the conducting bridge.

As V increases, the time to reach stage (iii) i.e. the formation of the conducting filament, reduces. Measurements performed on a number of different devices resulted in varying amounts of starting current values for the respective devices. The differences in the starting currents are ascribed to small differences in the starting microstructure of the materials. A few key conclusions may be made from this data. Firstly, the observation of a time to threshold that is voltage dependent is consistent with a filament formation mechanism that is diffusive and activation energy barrier limited. The probability of a defect surmounting an energy barrier is given by:

P∝ve^{(E}^{_{B}}^{-qV)}/kT

where v is the frequency at which the charged defect (with charge q) attempts at “jumping” across the barrier, E_{B} is the height of the energy barrier that is reduced by the application of an electrical potential V seen by the defect. Therefore, the higher the applied voltage across the film, the higher the rates at which the defect hops from site to site. Additionally, it is also seen that a certain minimum voltage (Vₘᵢₙ) is required to induce filament formation. For the devices tested, the minimum voltage stress required was ˜2.1 V.

The second observation addresses the issue of variability that is observed in all of the filamentary breakdown devices seen to date, and links the variability to differences in the starting local microstructure of the device. Experimental data indicates that the time required for filament formation as a function of two variables: the applied voltage (Vₛₜᵣₑₛₛ) and the starting current (I₀) at time, t=0. The time to threshold is dependent on not only the Vₛₜᵣₑₛₛ, but also on the I₀. Lower I₀ and smaller Vₛₜᵣₑₛₛ results in longer time to threshold. This indicates that local microstructures from device to device are different—hence the different starting currents—and such differences clearly affect the filament formation. The observations are consistent with a model where the filament initiates at heterogeneous centers in the device that are created by variations in the oxide microstructure, and that their growth and configuration is different from device to device, leading to the observed variability.

In summary, the present disclosure provides a criterion for electrode metal selection applicable to cationic filamentary devices. In general, the criterion indicates that small cohesive energy (E_{c}), low heat of formation of metal oxide (ΔH) and small ionic radius are generally desirable for low energy cationic filament formation. Based on this criterion, it was then successfully identified and demonstrated the viability of Sn|HfO₂ based CBRAM devices. Comparable device performance to Cu|HfO₂ and Ag|HfO₂ devices which include a turn-on voltage of ˜3.4 V, a steep turn-on slope (8.75 mV per decade) and very fast switching (17 ns), establishes Sn|HfO₂ based CBRAM devices as a good alternative to Cu and Ag anodes. Sn, being isovalent with Si, has the distinct property of being compatible with Si CMOS technology, unlike Cu and Ag which are fast diffusers, contribute to electronic defect states, and require diffusion barriers and liners for incorporating into the back end of Si CMOS, and are likely incompatible for front-end applications. Use of Sn is well justified also by first principle calculations that elucidate the preferred atomistic pathways and lower diffusion barriers compared to Cu and Ag. Threshold and memory switching can be achieved by modulating the compliance current through the device. Time domain response to subthreshold voltage stress gives insights into the filament formation process, revealing the dependency of time to threshold on the applied voltage as well as the initial leakage current through the device.

### II. Example Devices

Example devices will now be described in relation to certain Figures. In reference to FIG. 7, a cationic filamentary (CF) device 700 could include a first electrode 710, a second electrode 704, and an insulator 706 disposed between the first electrode 710 and the second electrode 704 such that a positive bias applied to the second electrode 704 causes formation of a filament in the insulator extending from the second electrode 704 towards the first electrode 710.

The first electrode 710 includes an electrochemically inert material. In some embodiments, the electrochemically inert material could include at least one of: W, Pt, Au, Mo, Co, Cr, Al, Ru, Ir, Sc, doped poly-Si. TiW, or TaN. The first electrode 710 could be a transparent conducting electrode made of a material such as indium tin oxide (ITO), fluorine doped tin oxide (FTO), and doped zinc oxide e. g. Al-doped ZnO. Other electrochemically inert materials are considered and possible. In some embodiments, a thickness of the first electrode 710 could be between 4 nm to 100 nm. However, in other embodiments, the thickness of the first electrode 710 could be lesser or greater than such a range.

The second electrode 704 includes an electrochemically active material. The electrochemically active material is Sn. In some embodiments, Sn could be present as a component of an alloy or a compound. In some embodiments, the second electrode 704 could have a thickness between 20 nm to 100 nm. Other thicknesses of the second electrode 704 are possible and contemplated.

In some embodiments, the insulator 706 includes at least one of: HfO₂, Ta₂O₅, SiO₂, WO₃, MoOₓ, ZrO₂, ZnO, SrTiO₃, TiO₂, CeOₓ, ZnO, Al₂O₃, MoOₓ, GdOₓ, or AlN. In some embodiments, a thickness of the insulator is between 1 nm to 10 nm. However, other insulator thicknesses are possible and contemplated.

As described herein, device 700 could be configured to form a conductive filament between the first electrode 710 and the second electrode 704. The conductive filament is configured to provide a bistable resistance behavior when an applied voltage is applied between the first electrode and the second electrode. In some embodiments, the bistable resistance behavior could include a unipolar, bidirectional resistance switching behavior when the applied voltage corresponds to one or more threshold voltages. For example, the bistable resistance behavior could include an ON state of the device 700 and an OFF state of the device 700. The ON state could include a low resistance state and the OFF state could include a high resistance state. Furthermore, in some embodiments, the ON state could occur, or be triggered, upon applying a voltage to the second electrode with respect to the first electrode that is greater than one or more threshold voltages.

In some embodiments, CF device 700 could include a field oxide 708 disposed on the first electrode 710. In such scenarios the field oxide 708 could include a lithographically-defined and etched window 709 to the first electrode 710. As an example, the window 709 could include a diameter between 50 nm to 100 μm. However, other diameters and/or shapes of the window 709 are possible and contemplated.

In such scenarios, the insulator 706 is disposed between the second electrode 704 and the first electrode 710 within the window 709.

In some example embodiments, CF device 700 could include a capping layer 702 disposed on the second electrode 704. In some embodiments, the capping layer 702 includes Au. However, other electrically conductive materials are contemplated for the capping layer 702.

Additionally or alternatively, in some embodiments, CF device 700 could include a substrate 712. The first electrode 710 is disposed on the substrate 712. In some embodiments, the substrate 712 includes a SiO₂ layer. In other examples, the substrate 712 could be formed from other electrically-insulating materials.

### III. Example Systems

Various systems will now be described in relation to one or more Figures. In reference to FIGS. 6 and 7, a system 600 could include a plurality cationic filamentary (CF) devices (e.g., CF device 700) disposed in a crossbar arrangement. As an example, each CF device 700 of the plurality of CF devices includes a first electrode (e.g., first electrode 710). In such scenarios, the first electrode includes an electrochemically inert material, such as at least one of: W. Pt, Au, Mo, Co, Cr, Al, Ru, Ir Sc, doped poly-Si. TiW, or TaN. The first electrode 710 could be a transparent conducting electrode comprising materials such as indium tin oxide (ITO), fluorine doped tin oxide (FTO), and doped zinc oxide e. g. Al-doped ZnO. Other electrochemically inert materials are possible and contemplated.

In some embodiments, system 600 could include a substrate 612, a field oxide 608, and/or an insulator 606.

Each CF device also includes a second electrode (e.g., second electrode 704). In such scenarios, the second electrode includes an electrochemically active material. The electrochemically active material includes Sn. In some embodiments, Sn could be present as a component of an alloy or a compound. As an example, in some embodiments, the second electrode could consist of at least 10% Sn by weight or at least 50% Sn by weight. In other embodiments, the second electrode could consist of at least 75% Sn by weight or 95% Sn by weight. Other compositions of the second electrode are possible and contemplated. For example, in some embodiments, the weight percentage of Sn of the second electrode could be between 0%-100% of the overall second electrode mass.

Each CF device additionally includes an insulator (e.g., insulator 706) disposed between the first electrode and the second electrode. In some embodiments, the insulator could include at least one of: HfO₂, Ta₂O₅, SiO₂, WO₃, MoOₓ, ZrO₂, ZnO, SrTiO₃, TiO₂, CeOₓ, ZnO, Al₂O₃, MoOₓ, GdOₓ, or AlN.

In some embodiments, one or more of the first electrodes are electrically connected to a first electrode array 610. In such scenarios, the first electrode array 610 includes a plurality of first electrode bars 611a. 611b, 611c, 611d, and 611e.

Furthermore, in various embodiments, one or more of the second electrodes are electrically connected to a second electrode array 620. In some examples, the second electrode array 620 includes a plurality of second electrode bars 621a, 621b, 621c, 621d, and 621e.

In some embodiments, each CBRAM device of the plurality of CBRAM devices is configured to be individually electrically addressed by way of a combination of a respective first electrode bar (e.g., first electrode bar 611a, 611b, 611c, 611d, or 611e) and a respective second electrode bar (e.g., second electrode bar 621a, 621b, 621c, 621d, or 621e).

In example embodiments, the first electrode bars 611a, 611b. 611c, 611d, and 611e could be parallel to a first axis (e.g., the x-axis). In some embodiments, the second electrode bars 621a, 621b, 621c, 621d, and 621e could be parallel to a second axis (e.g., the y-axis). In some embodiments, the first axis is perpendicular to the second axis. In other words, the first electrode bars and the second electrode bars could form a cross bar network. It will be understood that other geometries are possible and contemplated to provide individual electrical connections to a plurality of CF devices.

As described herein, in some embodiments, one of the first electrode or the second electrode of a given CBRAM device could be connected to a corresponding first electrode bar and/or the second electrode bar via at least one transistor. For example, the at least one transistor could be connected to the CF device in series. The at least one transistor could provide a controllably switchable coupling between the CF device and the crossbar array (e.g., a 1S1R (1 selector-1 resistor) cell).

### IV. Example Methods

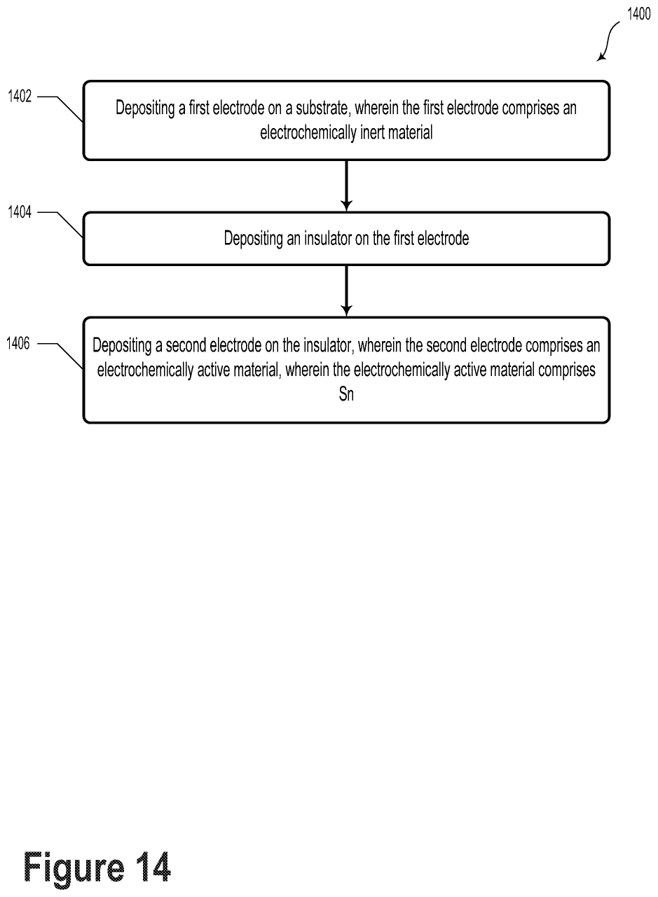

FIG. 14 illustrates a method 1400, according to an example embodiment. It will be understood that the method 1400 may include fewer or more steps or blocks than those expressly illustrated or otherwise disclosed herein. Furthermore, respective steps or blocks of method 1400 may be performed in any order and each step or block may be performed one or more times. In some embodiments, some or all of the blocks or steps of method 1400 may be carried out by involving one or more semiconductor processing tools or equipment. Method 1400 may be carried out in a semiconductor manufacturing environment (e.g., a cleanroom and/or semiconductor “fab”). It will be understood that other scenarios are possible and contemplated within the context of the present disclosure.

Method 1400 could include a method of manufacture of a cationic filamentary (CF) device and/or crossbar system, such as described within the context of the present disclosure. For example, method 1400 could be carried out to form some or all of the elements of system 600 and/or CF device 700, which are illustrated and described in relation to FIGS. 6 and 7, respectively.

Block 1402 in includes depositing a first electrode (e.g., first electrode 710) on a substrate (e.g., substrate 712). The first electrode includes an electrochemically inert material. In such scenarios, the electrochemically inert material could include at least one of W, Pt, Au, Mo, Co, Cr, Al, Ru, Ir, Sc, doped poly-Si, TiW, or TaN, and other transparent conducting electrode materials such as indium tin oxide (ITO), fluorine doped tin oxide (FTO), and doped zinc oxide e. g. Al-doped ZnO. In some embodiments, the first electrode could be deposited using an electron beam or RF sputtering process. Other ways to deposit the first electrode are possible and contemplated.

In an example embodiment, the substrate includes Si, however, other substrate materials are possible. For example, the substrate could include Ge, C, GaAs, GaSb, InAs, or another semiconductor substrate material.

Block 1404 includes depositing an insulator (e.g., insulator 706) on at least a portion of the first electrode. In some embodiments, the insulator could include one or more of: HfO₂, Ta₂O₅, SiO₂, WO₃, MoOₓ, ZrO₂, ZnO, SrTiO₃, TiO₂, CeOₓ, ZnO, Al₂O₃, MoOₓ, GdOₓ, or AlN. In various embodiments, depositing the insulator could be performed with an atomic layer deposition (ALD) system. However, the insulator could also be deposited using a chemical vapor deposition (CVD) process. Other ways to deposit the insulator are contemplated and possible.

Block 1406 includes depositing a second electrode (e.g., second electrode 704) on the insulator. The second electrode includes an electrochemically active material. In some scenarios, the electrochemically active material includes Sn. In some embodiments, Sn could be present as a component of an alloy or a compound. The electrochemically active material could be deposited using a sputtering technique or a CVD technique.

Method 1400 could include depositing a SiO₂ layer on the substrate. For example, prior to depositing the first electrode, the SiO₂ could be deposited using wet or dry oxidation process or a CVD technique. Other methods to deposit the SiO₂ layer are possible and contemplated.

In some embodiments, method 1400 could also include depositing a capping layer on the second electrode. In such scenarios, the capping layer could include Au. However, other materials are contemplated for the capping layer. In some embodiments, the capping layer could be deposited using a metal deposition technique, such as electron beam sputtering or a metal plating technique.

In various embodiments, method 1400 could include depositing a field oxide on the insulator. In some embodiments, the field oxide could be deposited using a PECVD oxide deposition process. In other embodiments, the field oxide could be deposited using a wet or dry oxidation process. It will be understood that other ways to deposit an insulating field oxide are possible and contemplated.

Method 1400 could additionally include lithographically-defining and etching a window through the field oxide to the first electrode. In some embodiments, the field oxide could be patterned and removed by way of photolithography and a wet and/or dry oxide etchback process. In other embodiments, electron beam lithography or another type of direct beam lithography could be utilized.

As described elsewhere herein, in some embodiments, the method 1400 is compatible with Si CMOS fabrication processes. That is, the constituent device materials and related fabrication steps to deposit and define those materials could be specifically selected and/or developed so as to avoid damage or performance degradation to Si CMOS devices. Furthermore, method 1400 could be integrated in to a Si CMOS fabrication process so as to provide CF devices along with Si CMOS devices on the same substrate. As such, method 1400 could be performed in a semiconductor cleanroom or a similar semiconductor device processing environment.

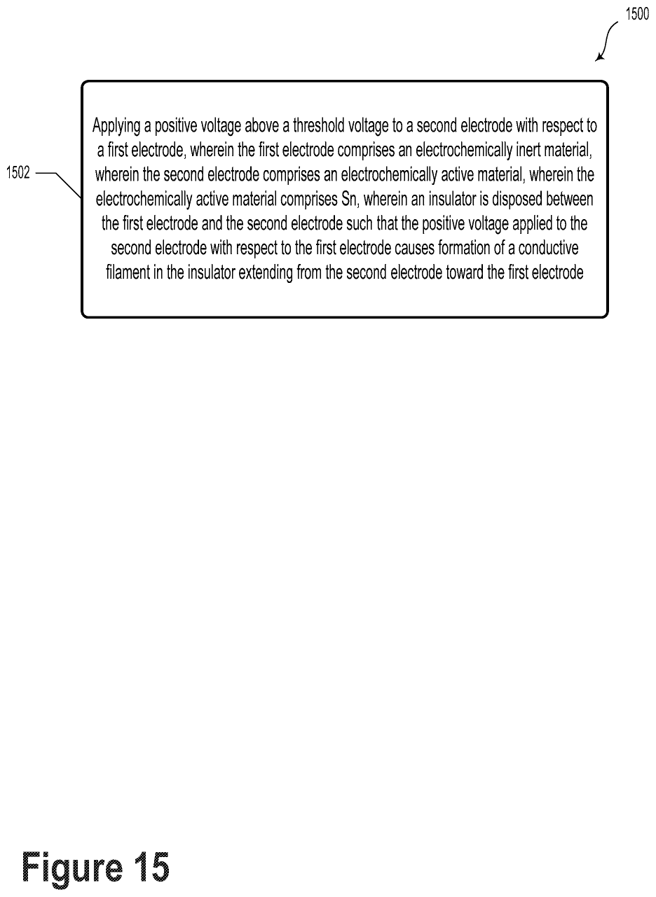

FIG. 15 illustrates a method 1500, according to an example embodiment. The method 1500 could be performed with and/or in relation to cationic filamentary (CF) devices, such as system 600 or CF device 700, illustrated and described in reference to FIGS. 6 and 7. The method 1500 includes applying a positive voltage above a threshold voltage to a second electrode (e.g., second electrode 704) with respect to a first electrode (e.g., first electrode 710). The first electrode includes an electrochemically inert material and the second electrode includes an electrochemically active material. The electrochemically active material includes Sn. An insulator (e.g., insulator 706) is disposed between the first electrode and the second electrode such that the positive voltage applied to the second electrode with respect to the first electrode causes formation of a conductive filament in the insulator extending from the second electrode toward the first electrode.

The particular arrangements shown in the Figures should not be viewed as limiting. It should be understood that other embodiments may include more or less of each element shown in a given Figure. Further, some of the illustrated elements may be combined or omitted. Yet further, an illustrative embodiment may include elements that are not illustrated in the Figures.

While various examples and embodiments have been disclosed, other examples and embodiments will be apparent to those skilled in the art. The various disclosed examples and embodiments are for purposes of illustration and are not intended to be limiting, with the true scope being indicated by the following claims.

1. A cationic filamentary (CF) device comprising:
a first electrode, wherein the first electrode comprises an electrochemically inert material;
a second electrode, wherein the second electrode comprises an electrochemically active material, wherein the electrochemically active material comprises Sn; and
an insulator disposed between the first electrode and the second electrode such that a positive voltage applied to the second electrode with respect to the first electrode causes formation of a conductive filament in the insulator extending from the second electrode toward the first electrode.

2. The CF device according to claim 1, wherein the electrochemically inert material comprises at least one of: W, Pt, Au, Mo, Co, Cr, Al, Ru, Ir, Sc, doped poly-Si, TiW, or TaN, indium tin oxide (ITO), fluorine doped tin oxide (FTO), and doped zinc oxide.

3. The CF device according to claim 1, wherein Sn is present as a component of an alloy or compound.

4. The CF device according to claim 1, wherein the insulator comprises at least one of: HfO₂, Ta₂O₅, SiO₂, WO₃, MoOₓ, ZrO₂, ZnO, SrTiO₃, TiO₂, CeOₓ, ZnO, Al₂O₃, MoOₓ, GdOₓ, and AlN.

5. The CF device according to claim 1, further comprising a conductive filament formed between the first electrode and the second electrode by way of applying a positive voltage above a threshold voltage to the second electrode with respect to the first electrode.

6. The CF device according to claim 1, wherein the CF device provides a bistable resistance behavior, wherein the bistable resistance behavior comprises an ON state and an OFF state, wherein the ON state comprises a low resistance state and wherein the OFF state comprises a high resistance state, wherein the ON state occurs upon applying a voltage greater than one or more threshold voltages to the second electrode with respect to the first electrode.

7. The CF device according to claim 1, wherein a thickness of the first electrode is between 4 nm and 100 nm.

8. The CF device according to claim 1, wherein a thickness of the insulator is between 1 nm to 10 nm.

9. The CF device according to claim 1, wherein a thickness of the second electrode is between 20 nm to 100 nm.

10. The CF device of according to claim 1, further comprising:
a field oxide disposed on the first electrode, wherein the field oxide comprises a lithographically-defined and etched window to the first electrode.

11. The CF device according to claim 10, wherein the window comprises a diameter between 50 nm to 100 μm.

12. The CF device according to claim 10, wherein the insulator is disposed between the second electrode and the first electrode within the window.

13. The CF device according to claim 1, further comprising:
a capping layer disposed on the second electrode, wherein the capping layer comprises Au; and
a substrate, wherein the first electrode is disposed on the substrate, wherein the substrate comprises a SiO₂ layer.

14. A system comprising:
a plurality of cationic filamentary (CF) devices disposed in a crossbar arrangement, wherein each CF device of the plurality of CF devices comprises:
a first electrode, wherein the first electrode comprises an electrochemically inert material;
a second electrode, wherein the second electrode comprises an electrochemically active material, wherein the electrochemically active material comprises Sn; and
an insulator disposed between the first electrode and the second electrode.

15. (canceled)

16. (canceled)

17. (canceled)

18. The system according to 14, further comprising a first array of parallel first electrode bars and a second array of parallel second electrode bars, wherein each first electrode is electrically connected to one of the first electrode bars of the first array, wherein each second electrode is electrically connected to one of the second electrode bars of the second array.

19. (canceled)

20. (canceled)

21. (canceled)

22. (canceled)

23. A method of manufacture of a cationic filamentary (CF) device, the method comprising:
depositing a first electrode on a substrate, wherein the first electrode comprises an electrochemically inert material;
depositing an insulator on the first electrode; and
depositing a second electrode on the insulator, wherein the second electrode comprises an electrochemically active material, wherein the electrochemically active material comprises Sn.

24. The method according to claim 23, wherein the electrochemically inert material comprises at least one of: W, Pt, Au, Mo, Co, Cr, Al, Ru, Ir, Sc, doped poly-Si, TiW, TaN, indium tin oxide (ITO), fluorine doped tin oxide (FTO), and doped zinc oxide.

25. The method according to claim 23, wherein Sn is present as a component of an alloy or compound.

26. The method according to claim 23, wherein the insulator comprises at least one of: HfO₂, Ta₂O₅, SiO₂, WO₃, MoOₓ, ZrO₂, ZnO, SrTiO₃, TiO₂, CeOₓ, ZnO, Al₂O₃, MoOₓ, GdOₓ, and AlN.

27. The method according to claim 23, wherein depositing the insulator is performed with an atomic layer deposition (ALD) system.

28. (canceled)

29. (canceled)

30. (canceled)

31. (canceled)

32. (canceled)

33. (canceled)

34. (canceled)
